(19) United States
(12) Patent Application Publication
(10) Pub. No.: US 2026/0149461 A1
(43) Pub. Date: May 28, 2026

(54) MIXED-MODE DIGITAL-TO-ANALOG CONVERTER

(71) Applicant: QUALCOMM Incorporated, San Diego, CA (US)

(72) Inventors: Negar RASHIDI, Mission Viejo, CA (US); Ashok SWAMINATHAN, Cardiff, CA (US); Beomsoo PARK, San Diego, CA (US)

(21) Appl. No.: 18/957,177

(22) Filed: Nov. 22, 2024

(51) Int. Cl. H03M 1/74; H04B 1/04

(52) U.S. Cl. CPC H03M 1/742; H04B 1/04

(57) ABSTRACT

Certain aspects of the present disclosure generally relate to electronic circuits and, more particularly, to digital-to-analog converters (DACs). One example apparatus for digital-to-analog conversion generally includes: a first multiplexer comprising a first input coupled to a first data input of the apparatus and a second input coupled to a second data input of the apparatus; a first DAC having an input coupled to an output of the first multiplexer; and a first set of switches coupled between an output of the first DAC and a respective one of a first set of load circuits.

### TECHNICAL FIELD

Certain aspects of the present disclosure generally relate to electronic circuits and, more particularly, to digital-to-analog converters (DACs).

### BACKGROUND

Wireless communication devices are widely deployed to provide various communication services such as telephony, video, data, messaging, broadcasts, and so on. Such wireless communication devices may transmit and/or receive radio frequency (RF) signals via any of various suitable radio access technologies (RATs) including, but not limited to, Fifth Generation (5G) New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., WiFi), and the like.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station. The base station and/or mobile station may include a transmission digital-to-analog converter (TxDAC), which may be used, for example, to convert a digital signal to an analog signal for signal processing (e.g., filtering, upconverting, and amplifying) before transmission by one or more antennas.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include a digital-to-analog converter (DAC) with reduced area consumption.

Certain aspects of the present disclosure are directed towards an apparatus for digital-to-analog conversion. The apparatus generally includes: a first multiplexer comprising a first input coupled to a first data input of the apparatus and a second input coupled to a second data input of the apparatus; a first digital-to-analog converter (DAC) having an input coupled to an output of the first multiplexer; and a first set of switches coupled between an output of the first DAC and a respective one of a first set of load circuits.

Certain aspects of the present disclosure are directed towards a method for digital-to-analog conversion. The method generally includes: providing, via a first multiplexer, first input data and second input data to an input of a first digital-to-analog converter (DAC) during a first phase and a second phase, respectively; generating, via the first DAC, a first analog signal and a second analog signal based on the first input data and the second input data during the first phase and the second phase, respectively; and providing the first analog signal and the second analog signal to a first load circuit and a second load circuit during the first phase and the second phase, respectively.

Certain aspects of the present disclosure are directed towards a transmitter. The transmitter generally includes: a set of baseband filters; a digital-to-analog converter (DAC) circuit comprising a multiplexer comprising a first input coupled to a first data input of the DAC circuit a second input coupled to a second data input of the DAC circuit, and a DAC having an input coupled to an output of the multiplexer; a first set of switches coupled between an output of the DAC circuit and a respective one of the set of baseband filters; and a set of mixers coupled to respective outputs of the set of baseband filters.

Certain aspects of the present disclosure are directed towards an apparatus for digital-to-analog conversion. The apparatus generally includes a first plurality of switch drivers, and a first plurality of current-steering cells coupled to the first plurality of switch drivers, respectively, wherein each of the first plurality of current-steering cells comprises: a first current source; a first switch pair coupled between the first current source and a first load; and a second switch pair coupled between the first current source and a second load.

Certain aspects of the present disclosure are directed towards a method for digital-to-analog conversion. The method generally includes: generating a first pair of control signals; generating a second pair of control signals; providing the first pair of control signals to respective control inputs of a first switch pair of a first cell of a first plurality of current-steering cells to generate a first analog signal; providing the second pair of control signals to respective control inputs of a second switch pair of the first cell to generate a second analog signal, wherein the first switch pair and the second switch pair are coupled to a current source of the first cell; providing the first analog signal to a first load; and providing the second analog signal to a second load.

Certain aspects of the present disclosure are directed towards a transmitter. The transmitter generally includes: a first baseband filter; a second baseband filter; a digital-to-analog converter (DAC) comprising a first plurality of switch drivers and a first plurality of current-steering cells coupled to the first plurality of switch drivers, respectively. Each of the first plurality of current-steering cells may include: a first current source; a first switch pair coupled between the first current source and the first baseband filter; and a second switch pair coupled between the first current source and the second baseband filter.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram conceptually illustrating a design of an example base station (BS) and user equipment (UE), in which aspects of the present disclosure may be practiced.

FIG. 3A is a block diagram of an example radio frequency (RF) transceiver, in which aspects of the present disclosure may be practiced.

FIG. 3B is a block diagram of an example RF transceiver with multiple transmit paths, in which aspects of the present disclosure may be practiced.

FIG. 4 is a circuit diagram of an example transmit circuit including a digital-to-analog converter (DAC) circuit, in accordance with certain aspects of the present disclosure.

FIGS. 5A and 5B illustrate graphs showing example analog output signals of a DAC and example input signals of a baseband filter (BBF), in accordance with certain aspects of the present disclosure.

FIG. 6 provides timing diagrams illustrating example clock and data signals of a transmit circuit, in accordance with certain aspects of the present disclosure.

FIG. 7 is a circuit diagram of an example transmit circuit including a data flip-flop and a non-overlapping clock generator, in accordance with certain aspects of the present disclosure.

FIGS. 8A and 8B illustrate graphs showing an in-phase (I) output signal of a DAC and an I with 45° phase offset (I45) output signal of the DAC, in accordance with certain aspects of the present disclosure.

FIG. 9 is a block diagram of an example DAC including current-steering cells, in accordance with certain aspects of the present disclosure.

FIG. 10 is a circuit diagram of an example switch driver circuit, in accordance with certain aspects of the present disclosure.

FIG. 11 is a flow diagram illustrating example operations for digital-to-analog conversion, in accordance with certain aspects of the present disclosure.

FIG. 12 is a block diagram of an example transmit circuit including a DAC with current-steering cells for generating I and I45 signals, in accordance with certain aspects of the present disclosure.

FIG. 13 is a circuit diagram of an example switch driver circuit, in accordance with certain aspects of the present disclosure.

FIG. 14 illustrates example operations for digital-to-analog conversion, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure relate to techniques and apparatus for digital-to-analog conversion. Some aspects are directed towards implementing digital-to-analog converters (DACs) with reduced area consumption as compared to conventional implementations. For instance, in-phase and quadrature (IQ) DAC circuitry may use four identical sub-DACs, each running at a sampling frequency (Fs) for providing digital-to-analog conversion for in-phase (I), I with a 45° phase shift (I45), quadrature (Q), and Q with a 45° phase shift (Q45) signals. To reduce area consumption, two sub-DACs may be removed, and the other two DACs may be operated at twice Fs (e.g., or each DAC may sample at both rising and falling edges of a clock signal). Thus, some aspects provide a mixed-mode DAC, which may be a DAC that performs conversion for different signals such as I and I45 signals. The DACs may be coupled to return-to-zero (RZ) baseband filters (BBFs), as described in more detail herein. Every other sample of the DAC may be provided to a different BBF as a RZ signal.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

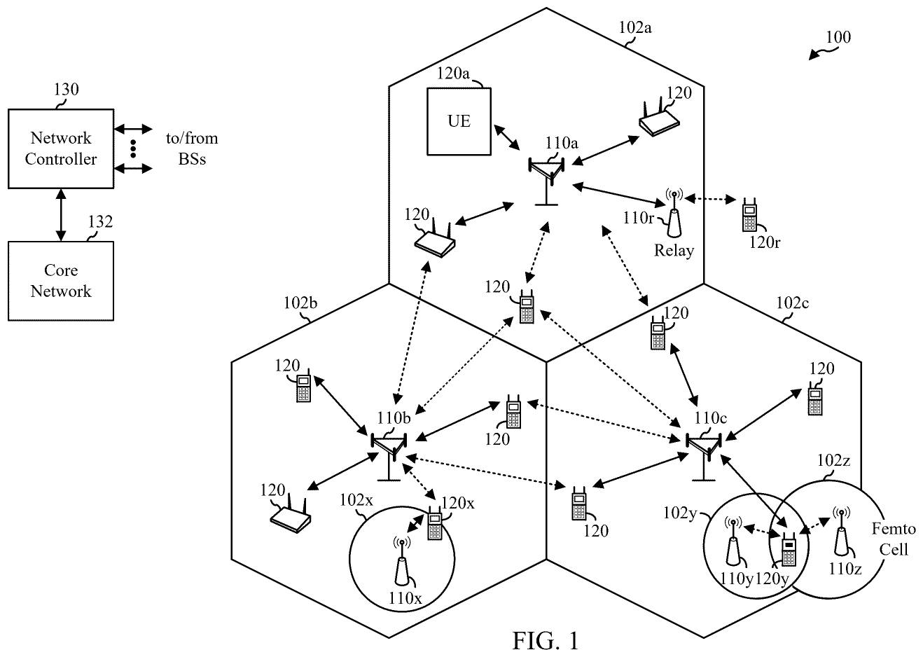

FIG. 1 illustrates an example wireless communications network 100, in which aspects of the present disclosure may be practiced. For example, the wireless communications network 100 may be a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation/Third Generation (2G/3G) network), or a code division multiple access (CDMA) system (e.g., a 2G/3G network), or may be configured for communications according to an IEEE standard such as one or more of the 802.11 standards, etc.

As illustrated in FIG. 1, the wireless communications network 100 may include a number of base stations (BSs) 110a-z (each also individually referred to herein as “BS 110” or collectively as “BSs 110”) and other network entities. A BS may also be referred to as an access point (AP), an evolved Node B (eNodeB or eNB), a next generation Node B (gNodeB or gNB), or some other terminology.

A BS 110 may provide communication coverage for a particular geographic area, sometimes referred to as a “cell,” which may be stationary or may move according to the location of a mobile BS. In some examples, the BSs 110 may be interconnected to one another and/or to one or more other BSs or network nodes (not shown) in wireless communications network 100 through various types of backhaul interfaces (e.g., a direct physical connection, a wireless connection, a virtual network, or the like) using any suitable transport network. In the example shown in FIG. 1, the BSs 110a, 110b, and 110c may be macro BSs for the macro cells 102a, 102b, and 102c, respectively. The BS 110x may be a pico BS for a pico cell 102x. The BSs 110y and 110z may be femto BSs for the femto cells 102y and 102z, respectively. A BS may support one or multiple cells.

The BSs 110 communicate with one or more user equipments (UEs) 120a-y (each also individually referred to herein as “UE 120” or collectively as “UEs 120”) in the wireless communications network 100. A UE may be fixed or mobile and may also be referred to as a user terminal (UT), a mobile station (MS), an access terminal, a station (STA), a client, a wireless device, a mobile device, or some other terminology. A user terminal may be a wireless device, such as a cellular phone, a smartphone, a personal digital assistant (PDA), a handheld device, a wearable device, a wireless modem, a laptop computer, a tablet, a personal computer, etc.

The BSs 110 are considered transmitting entities for the downlink and receiving entities for the uplink. The UEs 120 are considered transmitting entities for the uplink and receiving entities for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink. Nᵤₚ UEs may be selected for simultaneous transmission on the uplink, N_{dn} UEs may be selected for simultaneous transmission on the downlink. Nᵤₚ may or may not be equal to N_{dn}, and Nᵤₚ and N_{dn} may be static values or can change for each scheduling interval. Beam-steering or some other spatial processing technique may be used at the BSs 110 and/or UEs 120.

The UEs 120 (e.g., 120x, 120y, etc.) may be dispersed throughout the wireless communications network 100, and each UE 120 may be stationary or mobile. The wireless communications network 100 may also include relay stations (e.g., relay station 110r), also referred to as relays or the like, that receive a transmission of data and/or other information from an upstream station (e.g., a BS 110a or a UE 120r) and send a transmission of the data and/or other information to a downstream station (e.g., a UE 120 or a BS 110), or that relays transmissions between UEs 120, to facilitate communication between devices.

The BSs 110 may communicate with one or more UEs 120 at any given moment on the downlink and uplink. The downlink (i.e., forward link) is the communication link from the BSs 110 to the UEs 120, and the uplink (i.e., reverse link) is the communication link from the UEs 120 to the BSs 110. A UE 120 may also communicate peer-to-peer with another UE 120.

The wireless communications network 100 may use multiple transmit and multiple receive antennas for data transmission on the downlink and uplink. BSs 110 may be equipped with a number Nₐₚ of antennas to achieve transmit diversity for downlink transmissions and/or receive diversity for uplink transmissions. A set Nᵤ of UEs 120 may receive downlink transmissions and transmit uplink transmissions. Each UE 120 may transmit user-specific data to and/or receives user-specific data from the BSs 110. In general, each UE 120 may be equipped with one or multiple antennas. The Nᵤ UEs 120 can have the same or different number of antennas.

The wireless communications network 100 may be a time division duplex (TDD) system or a frequency division duplex (FDD) system. For a TDD system, the downlink and uplink share the same frequency band. For an FDD system, the downlink and uplink use different frequency bands. The wireless communications network 100 may also utilize a single carrier or multiple carriers for transmission. Each UE 120 may be equipped with a single antenna (e.g., to keep costs down) or multiple antennas (e.g., where the additional cost can be supported).

A network controller 130 (also sometimes referred to as a “system controller”) may be in communication with a set of BSs 110 and provide coordination and control for these BSs 110 (e.g., via a backhaul). In certain cases (e.g., in a 5G NR system), the network controller 130 may include a centralized unit (CU) and/or a distributed unit (DU). In certain aspects, the network controller 130 may be in communication with a core network 132 (e.g., a 5G Core Network (5GC)), which provides various network functions such as Access and Mobility Management, Session Management, User Plane Function, Policy Control Function, Authentication Server Function, Unified Data Management, Application Function, Network Exposure Function, Network Repository Function, Network Slice Selection Function, etc.

In certain aspects of the present disclosure, the BSs 110 and/or the UEs 120 may include a digital-to-analog converter (DAC) with reduced area consumption, as described in more detail herein.

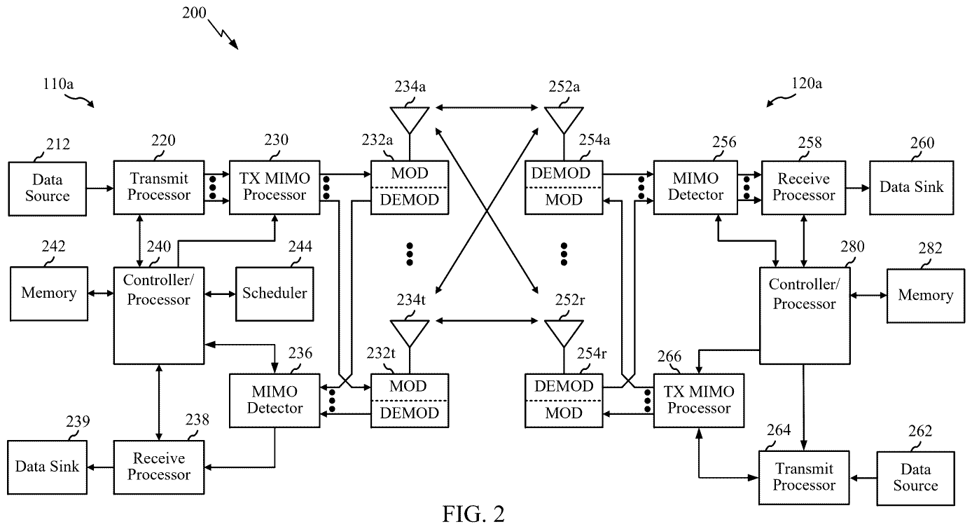

FIG. 2 illustrates example components of BS 110a and UE 120a (e.g., from the wireless communications network 100 of FIG. 1), in which aspects of the present disclosure may be implemented.

On the downlink, at the BS 110a, a transmit processor 220 may receive data from a data source 212, control information from a controller/processor 240, and/or possibly other data (e.g., from a scheduler 244). The various types of data may be sent on different transport channels. For example, the control information may be designated for the physical broadcast channel (PBCH), physical control format indicator channel (PCFICH), physical hybrid automatic repeat request (HARQ) indicator channel (PHICH), physical downlink control channel (PDCCH), group common PDCCH (GC PDCCH), etc. The data may be designated for the physical downlink shared channel (PDSCH), etc. A medium access control (MAC)-control element (MAC-CE) is a MAC layer communication structure that may be used for control command exchange between wireless nodes. The MAC-CE may be carried in a shared channel such as a PDSCH, a physical uplink shared channel (PUSCH), or a physical sidelink shared channel (PSSCH).

The processor 220 may process (e.g., encode and symbol map) the data and control information to obtain data symbols and control symbols, respectively. The transmit processor 220 may also generate reference symbols, such as for the primary synchronization signal (PSS), secondary synchronization signal (SSS), PBCH demodulation reference signal (DMRS), and channel state information reference signal (CSI-RS).

A transmit (TX) multiple-input, multiple-output (MIMO) processor 230 may perform spatial processing (e.g., precoding) on the data symbols, the control symbols, and/or the reference symbols, if applicable, and may provide output symbol streams to the modulators (MODs) in transceivers 232a-232t. Each modulator in transceivers 232a-232t may process a respective output symbol stream (e.g., for orthogonal frequency division multiplexing (OFDM), etc.) to obtain an output sample stream. Each of the transceivers 232a-232t may further process (e.g., convert to analog, amplify, filter, and upconvert) the output sample stream to obtain a downlink signal. Downlink signals from the transceivers 232a-232t may be transmitted via the antennas 234a-234t, respectively.

At the UE 120a, the antennas 252a-252r may receive the downlink signals from the BS 110a and may provide received signals to the transceivers 254a-254r, respectively. The transceivers 254a-254r may condition (e.g., filter, amplify, downconvert, and digitize) a respective received signal to obtain input samples. Each demodulator (DEMOD) in the transceivers 232a-232t may further process the input samples (e.g., for OFDM, etc.) to obtain received symbols. A MIMO detector 256 may obtain received symbols from all the demodulators in transceivers 254a-254r, perform MIMO detection on the received symbols if applicable, and provide detected symbols. A receive processor 258 may process (e.g., demodulate, deinterleave, and decode) the detected symbols, provide decoded data for the UE 120a to a data sink 260, and provide decoded control information to a controller/processor 280.

On the uplink, at UE 120a, a transmit processor 264 may receive and process data (e.g., for the physical uplink shared channel (PUSCH)) from a data source 262 and control information (e.g., for the physical uplink control channel (PUCCH)) from the controller/processor 280. The transmit processor 264 may also generate reference symbols for a reference signal (e.g., the sounding reference signal (SRS)). The symbols from the transmit processor 264 may be precoded by a TX MIMO processor 266 if applicable, further processed by the modulators (MODs) in transceivers 254a-254r (e.g., for single-carrier frequency division multiplexing (SC-FDM), etc.), and transmitted to the BS 110a. At the BS 110a, the uplink signals from the UE 120a may be received by the antennas 234, processed by the demodulators in transceivers 232a-232t, detected by a MIMO detector 236 if applicable, and further processed by a receive processor 238 to obtain decoded data and control information sent by the UE 120a. The receive processor 238 may provide the decoded data to a data sink 239 and the decoded control information to the controller/processor 240.

The memories 242 and 282 may store data and program codes for BS 110a and UE 120a, respectively. The memories 242 and 282 may also interface with the controllers/processors 240 and 280, respectively. A scheduler 244 may schedule UEs for data transmission on the downlink and/or uplink.

Antennas 252, processors 258, 264, 266, and/or controller/processor 280 of the UE 120a and/or antennas 234, processors 220, 230, 238, and/or controller/processor 240 of the BS 110a may be used to perform the various techniques and methods described herein.

In certain aspects of the present disclosure, the transceivers 232 and/or the transceivers 254 may include a DAC with reduced area consumption, as described in more detail herein.

NR may utilize orthogonal frequency division multiplexing (OFDM) with a cyclic prefix (CP) on the uplink and downlink. NR may support half-duplex operation using time division duplexing (TDD). OFDM and single-carrier frequency division multiplexing (SC-FDM) partition the system bandwidth into multiple orthogonal subcarriers, which are also commonly referred to as tones, bins, etc. Each subcarrier may be modulated with data. Modulation symbols may be sent in the frequency domain with OFDM and in the time domain with SC-FDM. The spacing between adjacent subcarriers may be fixed, and the total number of subcarriers may be dependent on the system bandwidth. The system bandwidth may also be partitioned into subbands. For example, a subband may cover multiple resource blocks (RBs).

### Introduction to Mmwave Wireless Communications

In wireless communications, an electromagnetic spectrum is often subdivided into various classes, bands, channels, or other features. The subdivision is often provided based on wavelength or frequency, where frequency may also be referred to as a carrier, a subcarrier, a frequency channel, a tone, or a subband.

5G networks may utilize several frequency ranges, which in some cases are defined by a standard, such as the 3^{rd} Generation Partnership Project (3GPP) standards. For example, 3GPP technical standard TS 38.101 currently defines Frequency Range 1 (FR 1) as including 600 MHz- 6 GHz, though specific uplink and downlink allocations may fall outside of this general range. Thus, FR1 is often referred to (interchangeably) as a “sub-6 GHz” band.

Similarly, TS 38.101 currently defines Frequency Range 2 (FR2) as including 26-41 GHz, though again specific uplink and downlink allocations may fall outside of this general range. FR2, is sometimes referred to (interchangeably) as a “millimeter wave” (“mmW” or “mmWave”) band, despite being different from the extremely high frequency (EHF) band (30 GHz-300 GHz) that is identified by the International Telecommunications Union (ITU) as a “millimeter wave” band because wavelengths at these frequencies are between 1 millimeter and 10 millimeters.

Communications using mmWave/near mmWave radio frequency band (e.g., 3 GHz-300 GHz) may have higher path loss and a shorter range compared to lower frequency communications. As described above with respect to FIG. 1, a base station (e.g., base station 110) configured to communicate using mmWave/near mmWave radio frequency bands may utilize beamforming with a UE (e.g., UE 120) to improve path loss and range.

### Example RF Transceiver

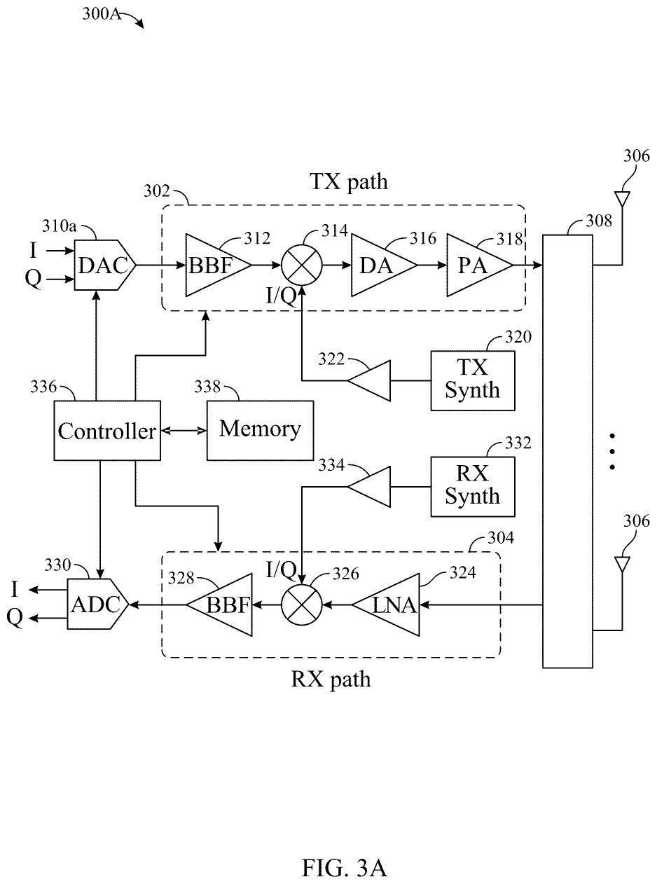

FIG. 3A is a block diagram of an example radio frequency (RF) transceiver circuit 300A, in accordance with certain aspects of the present disclosure. The RF transceiver circuit 300A includes at least one transmit (TX) path 302 (also known as a “transmit chain”) for transmitting signals via one or more antennas 306 and at least one receive (RX) path 304 (also known as a “receive chain”) for receiving signals via the antennas 306. When the TX path 302 and the RX path 304 share an antenna 306, the paths may be connected with the antenna via an interface 308, which may include any of various suitable RF devices, such as a switch, a duplexer, a diplexer, a multiplexer, and the like.

Receiving in-phase (I) and/or quadrature (Q) baseband analog signals from a digital-to-analog converter (DAC) 310a, the TX path 302 may include a baseband filter (BBF) 312, a mixer 314, a driver amplifier (DA) 316, and a power amplifier (PA) 318. The BBF 312, the mixer 314, the DA 316, and the PA 318 may be included in a radio frequency integrated circuit (RFIC). For certain aspects, the PA 318 may be external to the RFIC.

For certain aspects, the DAC 310a may be implemented by any of various suitable high-speed DAC topologies, such as a current-steering DAC. For certain aspects, the sampling frequency of the DAC 310a may be increased as compared to conventional implementations to reduce the size of the DAC, as described in more detail below. The BBF 312 filters the baseband signals received from the DAC 310a, and the mixer 314 mixes the filtered baseband signals with a transmit local oscillator (LO) signal to convert the baseband signal of interest to a different frequency (e.g., upconvert from baseband to a radio frequency). This frequency-conversion process produces the sum and difference frequencies between the LO frequency and the frequencies of the baseband signal of interest. The sum and difference frequencies are referred to as the “beat frequencies.” The beat frequencies are typically in the RF range, such that the signals output by the mixer 314 are typically RF signals, which may be amplified by the DA 316 and/or by the PA 318 before transmission by the antenna(s) 306. While one mixer 314 is illustrated, several mixers may be used to upconvert the filtered baseband signals to one or more intermediate frequencies and to thereafter upconvert the intermediate frequency signals to a frequency for transmission.

The RX path 304 may include a low noise amplifier (LNA) 324, a mixer 326, and a baseband filter (BBF) 328. The LNA 324, the mixer 326, and the BBF 328 may be included in one or more RFICs, which may or may not be the same RFIC that includes the TX path components. RF signals received via the antenna(s) 306 may be amplified by the LNA 324, and the mixer 326 mixes the amplified RF signals with a receive local oscillator (LO) signal to convert the RF signal of interest to a different baseband frequency (e.g., downconvert). The baseband signals output by the mixer 326 may be filtered by the BBF 328 before being converted by an analog-to-digital converter (ADC) 330 to digital I and/or Q signals for digital signal processing.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO may be produced by a TX frequency synthesizer 320, which may be buffered or amplified by amplifier 322 before being mixed with the baseband signals in the mixer 314. Similarly, the receive LO may be produced by an RX frequency synthesizer 332, which may be buffered or amplified by amplifier 334 before being mixed with the RF signals in the mixer 326. For certain aspects, a single frequency synthesizer may be used for both the TX path 302 and the RX path 304. In certain aspects, the TX frequency synthesizer 320 and/or RX frequency synthesizer 332 may include a frequency multiplier, such as a frequency doubler, that is driven by an oscillator (e.g., a VCO) in the frequency synthesizer.

A controller 336 (e.g., controller/processor 280 in FIG. 2) may direct the operation of the RF transceiver circuit 300A, such as transmitting signals via the TX path 302 and/or receiving signals via the RX path 304. The controller 336 may be a processor, a digital signal processor (DSP), an application-specific integrated circuit (ASIC), a field-programmable gate array (FPGA) or other programmable logic device (PLD), discrete gate or transistor logic, discrete hardware components, or any combination thereof. A memory 338 (e.g., memory 282 in FIG. 2) may store data and/or program codes for operating the RF transceiver circuit 300A. The controller 336 and/or the memory 338 may include control logic (e.g., complementary metal-oxide-semiconductor (CMOS) logic).

FIG. 3B is a block diagram of an example RF transceiver circuit 300B, in accordance with certain aspects of the present disclosure. The RF transceiver circuit 300B may be similar to the RF transceiver circuit 300A, but with multiple TX paths 302a and 302b (collectively referred to as “TX paths 302”). The TX path 302a may include a baseband filter (BBF) 312a, a mixer 314a, a driver amplifier (DA) 316a, and a power amplifier (PA) 318a. The TX path 302b may include similar components as the TX path 302a (e.g., a BBF 312b, a mixer 314b, a DA 316b, and a PA 318b). The components of the TX path 302a may be the same as or different than the components of the TX path 302b. The RF transceiver circuit 300B may also include a DAC 310b for supporting multiple radio access technologies (RATs), such as sub-6 GHz and mmWave transmissions.

The RF transceiver circuit 300B (and more specifically, the DAC 310b and TX paths 302) may support multiple radio transmission scenarios, such as for sub-6 GHz and millimeter wave (mmWave) radio transmission scenarios. For example, the RF transceiver circuit 300B may transmit signals using a first wireless communication technology operating at or below 6 GHz (e.g., 3G, 4G, 5G, etc.) and a second wireless communication technology operating above 6 GHz (e.g., mmWave 5G NR in 24 to 60 GHz bands, IEEE 802.11ad or 802.11ay). In one example, the RF transceiver circuit 300B may process sub-6 GHz signals through the TX path 302a, and may process mmWave signals through the TX path 302b (or vice versa). As used herein, sub-6 GHz bands may include frequency bands of 300 to 6000 MHz in some examples, and may include bands in the 6000 MHz and/or 7000 MHz range in some examples.

In some cases where the DAC 310b supports both sub-6 GHz and mmWave frequency ranges and utilizes a current-steering DAC topology, the DAC 310b may be referred to as a “converged current-steering DAC.” In converged current-steering DACs, a wide range of full-scale current (I_{FS}) is desirable due to different I_{FS} specifications for baseband filters at the different outputs of the DAC 310b (e.g., BBF 312a and 312b). In some examples, the DAC 310 b supports an I_{FS} equal to a base value (e.g., × or 1×) for sub-6 GHz technology, and an I_{FS} equal to two to four times the base value (e.g., 2× or 4×) for mmWave technology. In some examples, an I_{FS} equal to eight times the base value (e.g., 8×) may be desirable. For example, if an I_{FS} has a base value 1×=0.25 mA for sub-6 GHz, the I_{FS} may equal be equal to 0.50 or 1.00 mA for mmWave. Although shown as single-ended outputs, each output of the DAC 310b illustrated in FIG. 3B may represent a differential output current.

While FIGS. 1, 2, 3A, and 3B provide a wireless communication as an example application in which certain aspects of the present disclosure may be implemented to facilitate understanding, certain aspects described herein may be used for digital-to-analog conversion in any of various other suitable systems (e.g., an audio system or other electronic system).

### Example Techniques for Digital-to-analog Conversion

Current-steering digital-to-analog converters (DACs) are one example of an architecture for high-performance digital-to-analog conversion in many wireless transmitters. In some implementations, in-phase and quadrature (IQ) DAC circuitry may use four identical sub-DACs, each running at a sampling frequency (Fs) for providing digital-to-analog conversion for in-phase (I), I with a 45° phase shift (I45), quadrature (Q), and Q with a 45° phase shift (Q45) signals. To meet the ever-more-demanding area reduction specifications in digital-to-analog converters (DAC) (e.g., in fifth-generation (5G) radio frequency (RF) transmitters), some aspects of the present disclosure reduce the area of the DAC circuitry (e.g., by half) by removing two sub-DACs and operating each DAC at twice Fs or operating each DAC (e.g., sampling via each DAC) at both rising and falling edges of a clock signal. Certain aspects provide a mixed DAC with return-to-zero (RZ) baseband filters (BBFs). Each DAC may operate at twice Fs, with every other sample being provided to a different BBF as an RZ signal, as described in more detail herein.

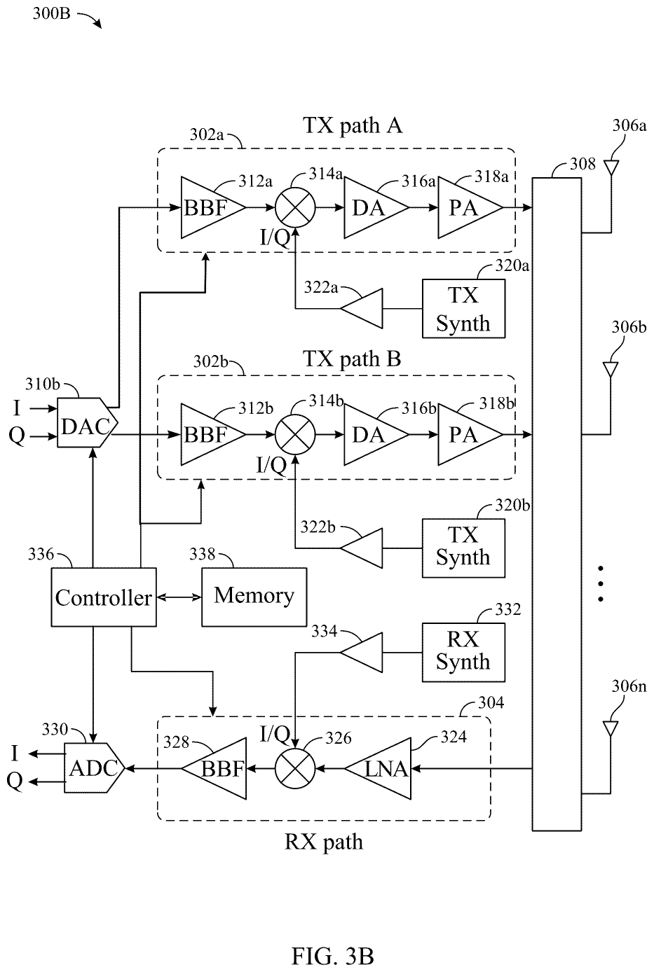

FIG. 4 is a circuit diagram of a transmit circuit 400 including a DAC circuit 450, in accordance with certain aspects of the present disclosure. The DAC circuit 450 includes an I and I45 DAC 402 and a Q and Q45 DAC 404. The DAC 402 may be selectively coupled to positive and negative inputs of a BBF 406 (e.g., for filtering I signals) via respective switches 430, 432 and selectively coupled to positive and negative inputs of a BBF 410 (e.g., for filtering I45 signals) via respective switches 434, 436. The DAC 404 may be selectively coupled to positive and negative inputs of a BBF 408 (e.g., for filtering Q signals) via respective switches 438, 440 and selectively coupled to positive and negative inputs of a BBF 412 (e.g., for filtering Q45 signals) via respective switches 442, 444. Differential outputs of the BBFs 406, 408, 410, 412 may be provided to inputs of respective mixers 414, 416, 418, 420 for upconversion. The LO inputs to the mixers 414, 416, 418, 420 are not shown in FIG. 4. The outputs of mixers 414, 416, 418, 420 may be provided to the DA 316 for amplification, as described herein.

As shown, the DAC circuitry 450 may include a multiplexer 422 that may receive, as inputs, I data (labeled “Din_I”) and I45 data (labeled “Din_I45”). The output of multiplexer 424 may be coupled to an input of the DAC 402. The DAC circuitry 450 may also include a multiplexer 424 that may receive, as inputs, Q data (labeled “Din_Q”) and Q45 data (labeled “Din_Q45”). The output of multiplexer 424 may be coupled to an input of the DAC 404.

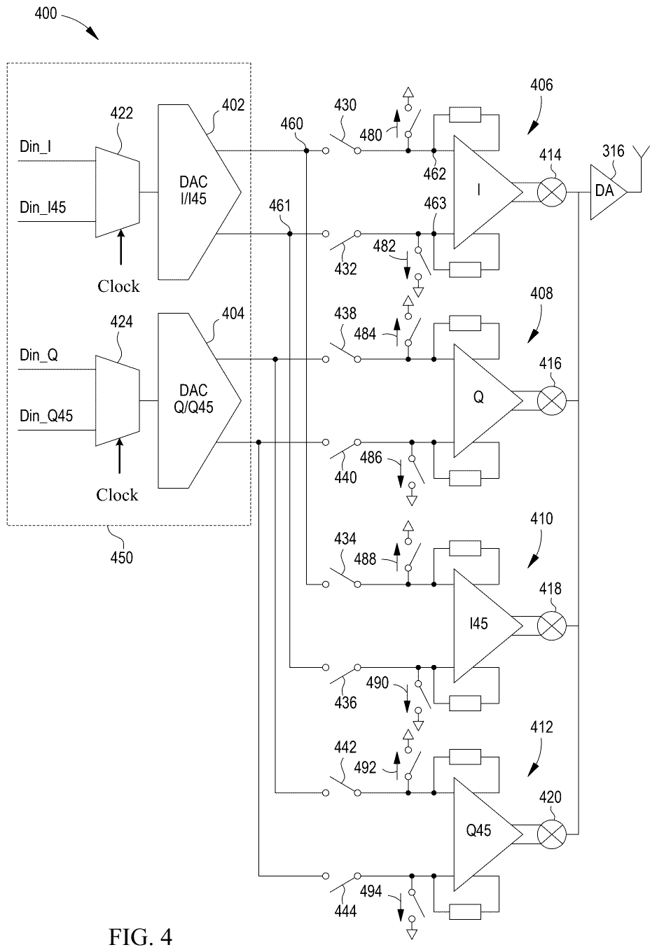

The DAC 402 may receive, from the multiplexer 422, Din_I during an I/Q conversion phase and generate an I analog signal that may be provided to BBF 406 by closing switches 430, 432. The DAC 402 may receive, from the multiplexer 422, Din_I45 during an I45/Q45 conversion phase and generate an I45 analog signal that may be provided to BBF 410 by closing switches 434, 436. Similarly, the DAC 404 may receive, from the multiplexer 424, Din_Q during the I/Q conversion phase and generate a Q analog signal that may be provided to BBF 408 by closing switches 438, 440. The DAC 404 may receive, from the multiplexer 424, Din_Q45 during the I45/Q45 conversion phase and generate a Q45 analog signal that may be provided to BBF 412 by closing switches 442, 444. The analog output of each DAC (e.g., between nodes 460, 461 at the output of DAC 402) may be a non-RZ (NRZ) signal. However, the signal at the input of each BBF (e.g., at node 462) may be an RZ signal as described in more detail with respect to FIGS. 5A and 5B.

FIG. 5A illustrates a graph 500 showing an example analog output signal of DAC 402 between nodes 460, 461, in accordance with certain aspects of the present disclosure. As shown, the DAC 402 may generate an I signal at node 460 representing Din_I (e.g., during the I/Q conversion phase) followed by an I45 signal at node 460 representing Din_I45 (e.g., during the I45/Q45 conversion phase). This process may be repeated, as shown. The curve 502 may represent the generated I signal, and the curve 504 may represent the generated I45 signal. As shown, the signal at node 460 is an NRZ signal.

FIG. 5B illustrates a graph 550 showing an example analog signal input to BBF 406 (e.g., at node 462), in accordance with certain aspects of the present disclosure. As shown, the DAC 402 may generate the I signal that is provided to an input (e.g., node 460) of BBF 406 through switch 430. After providing the I signal, the switch 430 may be opened, and the inputs of BBF 406 (e.g., such as the input at node 462) may be coupled to a reference potential node (e.g., electric ground) through respective shunt paths (e.g., shunt paths 480, 482 of FIG. 4) while the DAC 402 generates the I45 signal to be provided to BBF 410 as described herein. As shown, shunt paths 480, 482 may be coupled to respective differential inputs of BBF 406, shunt paths 484, 486 may be coupled to respective differential inputs of BBF 408, shunt paths 488, 490 may be coupled to respective differential inputs of BBF 410, and shunt paths 492, 494 may be coupled to respective differential inputs of BBF 412. Each shunt path may include a switch between a corresponding input of a BBF and the reference potential node. Due to the shunt paths, the signal at the inputs of each BBF may be an RZ signal as the inputs may be coupled to the reference potential node when corresponding switches (e.g., switches 430, 432 for BBF 406) are open. After generating the I45 signal, switches 430, 432 are closed to provide another I signal generated by DAC 402 to the BBF 406.

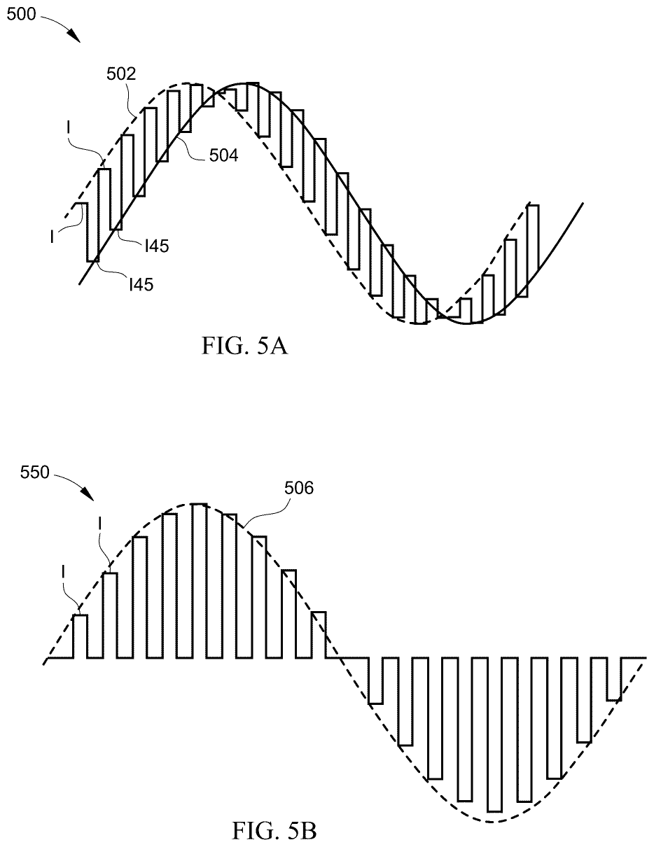

FIG. 6 provides timing diagrams 600, 650 illustrating example clock and data signals of the transmit circuit 400, in accordance with certain aspects of the present disclosure. As shown in timing diagram 600, a clock signal (e.g., having twice the sampling frequency of a typical DAC circuit) may be generated, where each clock cycle corresponds to an I/Q conversion phase or an I45/Q45 conversion phase. During the I/Q conversion phase, first I data (e.g., labeled “A-i”) may be converted, and first Q data (e.g., labeled “Q-i”) may be converted. During a subsequent cycle of the clock signal, a first I45 signal (e.g., labeled “A-i45”) may be generated, and a first Q45 signal (e.g., labeled “A-q45”) may be generated. This process may be repeated to convert subsequent I, Q, I45, and Q45 data labeled “B-i,” “B-q,” “B-i45,” and “B-q45,” respectively. As shown in timing diagram 650, instead of each cycle of the clock signal corresponding to an I/Q conversion phase or an I45/Q45 conversion phase, each conversion phase may span from a rising edge (or falling edge) to a falling edge (or rising edge) of the clock signal.

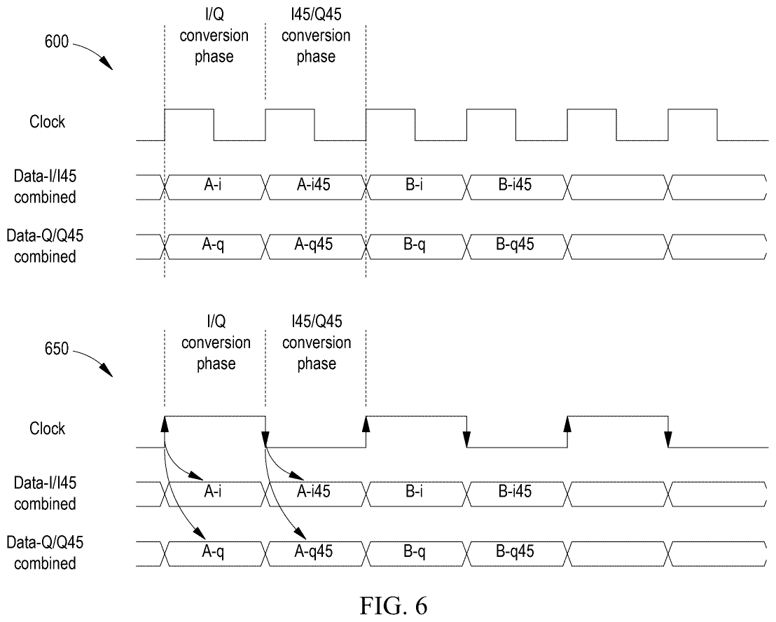

FIG. 7 is a circuit diagram of an example transmit circuit 700 including a data (D) flip-flop 702 (labeled “dff”) and a non-overlapping clock generator 704, in accordance with certain aspects of the present disclosure. The multiplexer 422 may provide one of Din_I and Din_I45 (the selected signal labeled “Din_I_I45”) to the DAC 402 based on a clock signal (labeled “Clock”), such as the clock signal shown in diagram 650 of FIG. 6. In some aspects, a transmitter clock (labeled “tx_ck”) signal may be provided to the DAC 402 and used to sample the data input Din_I_I45. The flip-flop 702 may be used to generate a switch control signal having half the frequency of the tx_ck signal. The switch control signal may be used to drive the switches 430, 432, 434, 436 such that switches 430, 432 are closed during the I/Q conversion phase and switches 434, 436 are closed during the I45/Q45 conversion phase. In some aspects, the non-overlapping clock generator 704 may be used to generate non-overlapping clock signals, where one non-overlapping clock signal is used to drive switches 430, 432 and another non-overlapping clock signal is used to drive switches 434, 436. Non-overlapping clock signals generally refer to clock signals that are logic high during non-overlapping periods.

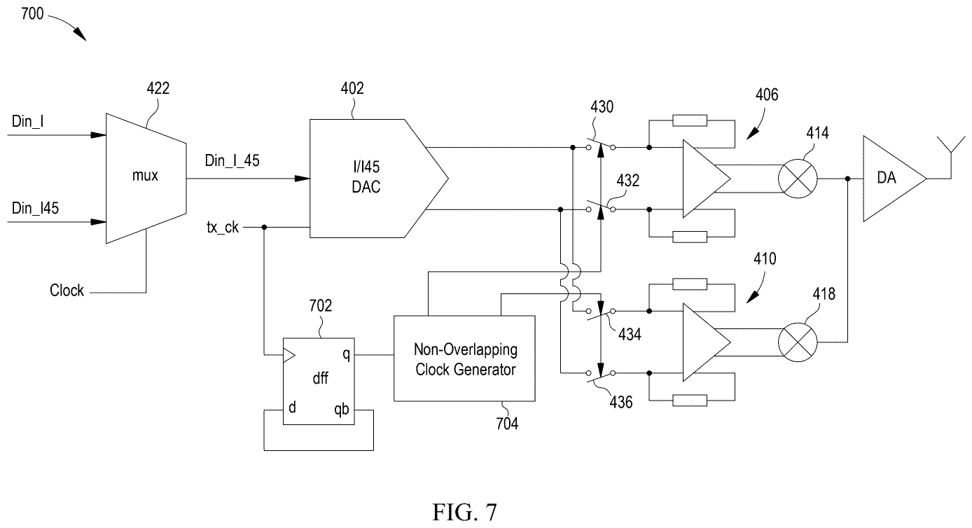

FIGS. 8A and 8B illustrate graphs 800, 850 showing an I output (Iout) signal of the DAC 402 and an I45 output (I45out) signal of the DAC 402, respectively, as provided to the inputs of respective BBFs 406, 410, in accordance with certain aspects of the present disclosure. As shown, when the I45out signal is being generated, the Iout signal may be at zero volts due to the corresponding BBF input being coupled to the reference potential node (e.g., electric ground) using a shunt path as described herein. Similarly, when the Iout signal is being generated, the I45 out signal may be at zero volts. The Q and Q45 output signals may be generated in a similar manner.

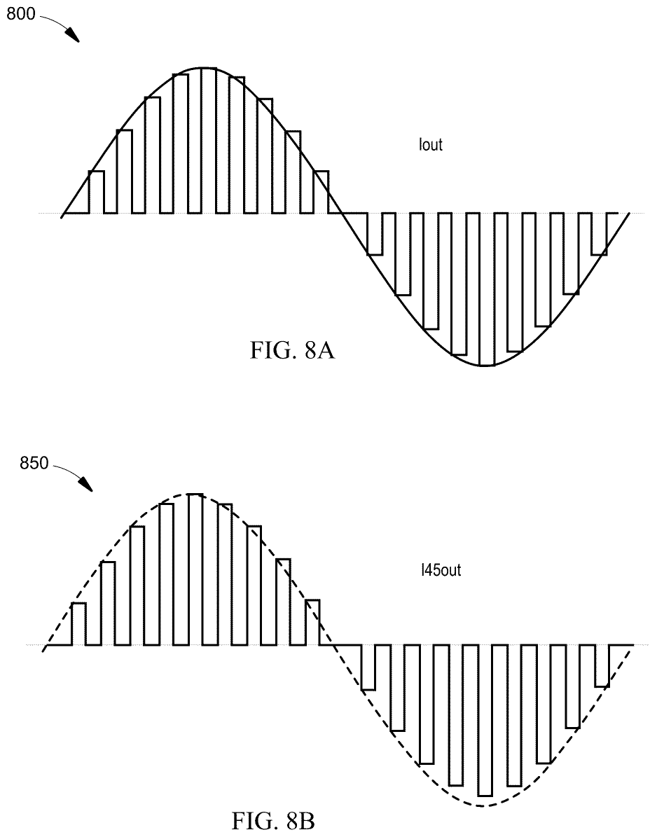

FIG. 9 is a block diagram of an example DAC 900 (e.g., an example implementation of the DAC 402) including current-steering cells, in accordance with certain aspects of the present disclosure. The DAC 900 may include switch drivers 1 to n, n being a positive integer. The switch drivers 1 to n may be used to control switches of respective current-steering cells 1 to n. Each of the current-steering cells 1 to n may include a current source coupled to current-steering transistors. For example, current-steering cell 1 may include a current source 902 coupled to current-steering transistors 904, 906. Depending on a digital input code, each bit of the DAC 900 associated with a current-steering cell may source a positive current or a negative current to respective outputs depending on the logic level for a respective bit of the digital input code. The transistor 904 may be controlled by a positive switch control (sw_p) signal, and the transistor 906 may be controlled by a negative switch control (sw_n) signal. The transistors 904, 906 may be p-type metal-oxide-semiconductor (PMOS) transistors, for example.

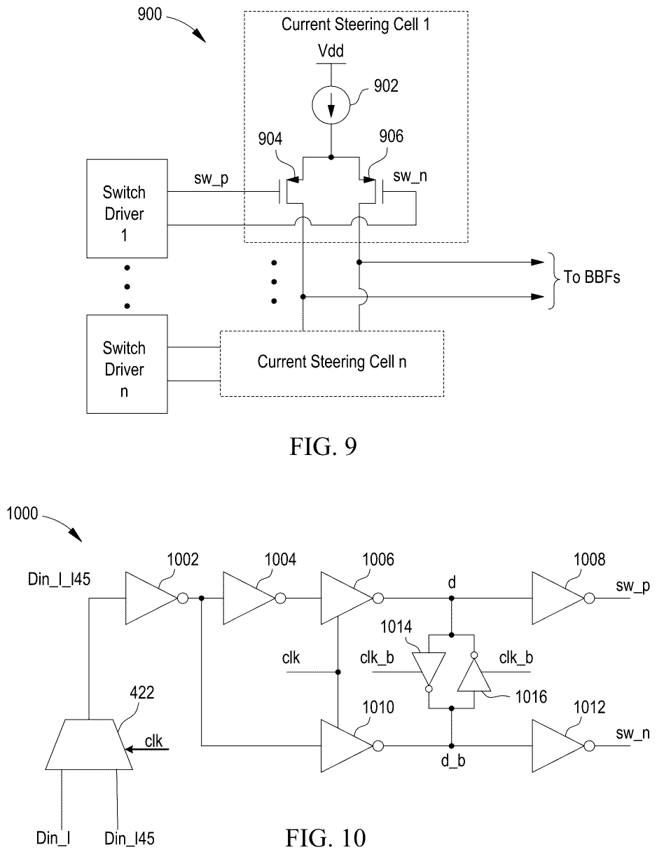

FIG. 10 is a circuit diagram of an example switch driver circuit 1000 used to generate the sw_p and sw_n signals, in accordance with certain aspects of the present disclosure. The switch driver circuit 1000 may correspond to each of the switch drivers 1 to n shown in FIG. 9. As shown, input data (Din_I_I45) may be received at an input of an inverter 1002 from the multiplexer 422. The output of inverter 1002 may be coupled to an input of inverter 1004 and an input of inverter 1010, and an output of inverter 1004 may be coupled to an input of inverter 1006. The inverters 1006, 1010 may perform inversion operations based on a clock signal (labeled “clk”) to generate a data signal labeled “d” at a data node and a complementary data signal labeled “db” at a complementary data node. The data signal d and the complementary data signal db may be inverted using respective inverters 1008, 1012 to generate the sw_p and sw_n signals used to drive the respective gates of transistors 904, 906 of FIG. 9. In some aspects, anti-parallel inverters 1014, 1016 may be coupled between the outputs of inverters 1006, 1010 to synchronize the data signal d and the complementary data signal db. For example, the output of inverter 1014 may be coupled to an input of inverter 1016 and to the output of inverter 1010. The output of inverter 1016 may be coupled to an input of inverter 1014 and to the output of inverter 1006. The inverters 1014, 1016 may perform inversion operations based on a complementary clock signal (labeled “clk_b) that is complementary to the clk signal.

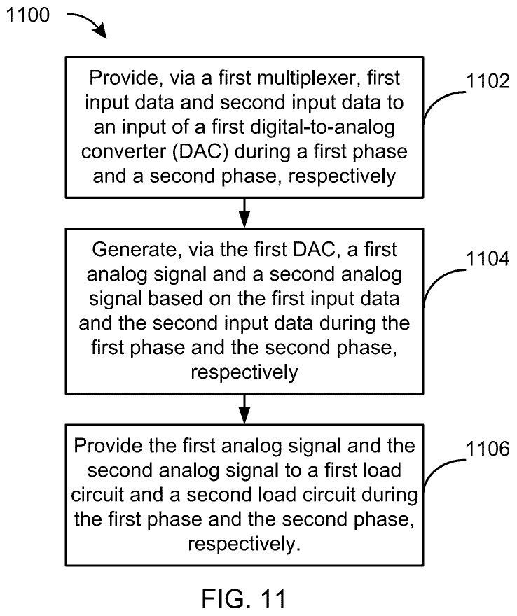

FIG. 11 is a flow diagram illustrating example operations 1100 for digital-to-analog conversion, in accordance with certain aspects of the present disclosure. The operations 1100 may be performed, for example, by a circuit such as the transmit circuit 400 of FIG. 4.

At block 1102, the circuit provides, via a first multiplexer (e.g., multiplexer 422), first input data (e.g., Din_I) and second input data (e.g., Din_I45) to an input of a first DAC (e.g., DAC 402) during a first phase (e.g., I/Q conversion phase) and a second phase (e.g., I45 and Q45 conversion phase), respectively. At block 1104, the circuit generates, via the first DAC, a first analog signal (e.g., I signal) and a second analog signal (e.g., I45 signal) based on the first input data and the second input data during the first phase and the second phase, respectively.

At block 1106, the circuit provides the first analog signal and the second analog signal to a first load circuit (e.g., a first baseband filter such as baseband filter 406) and a second load circuit (e.g., a second baseband filter such as baseband filter 410) during the first phase and the second phase, respectively. In some aspects, the first analog signal and the second analog signal are provided to the first baseband filter and the second baseband filter via a first switch (e.g., switch 430 or switch 432) and a second switch (e.g., switch 434 or switch 436), respectively.

In some aspects, the circuit couples, to a reference potential node, an input of the first baseband filter and the second baseband filter during the second phase and the first phase, respectively. In some aspects, input signals of the first baseband filter and the second baseband filter may be RZ signals (e.g., as described with respect to FIG. 5B).

In some aspects, the circuit may provide, via a second multiplexer (e.g., multiplexer 424), third input data (e.g., Din_Q) and fourth input data (e.g., Din_Q45) to an input of a second DAC (e.g., DAC 404) during the first phase and the second phase, respectively. The circuit may generate, via the second DAC, a third analog signal (e.g., Q signal) and a fourth analog signal (e.g., Q45 signal) based on the third input data and the fourth input data during the first phase and the second phase, respectively. The circuit may provide the third analog signal and the fourth analog signal to a third load circuit (e.g., baseband filter 408) and a fourth load circuit (e.g., baseband filter 412) during the first phase and the second phase, respectively. In some aspects, the first input data comprises an in-phase (I) input data, the second input data comprises an I with 45° phase shift (I45) input data, the third input data comprises a quadrature (Q) input data, and the fourth input data comprises a Q with 45° phase shift (Q45) input data.

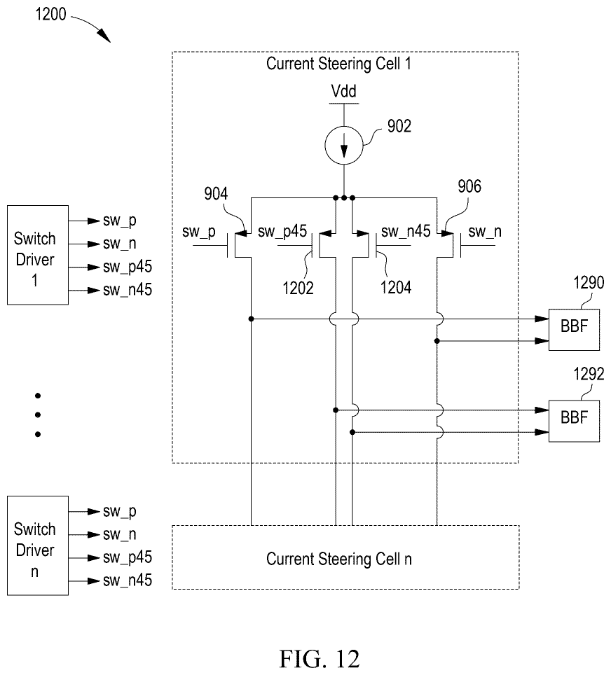

Certain aspects of the present disclosure are directed towards a switch-driver-based implementation for a DAC. For instance, instead of using the switches 430, 432, 434, 436, 438, 440, 442, 444 to selectively provide an output of a DAC to different BBFs as described with respect to FIG. 4, the switches of the current-steering cells may be used to generate different outputs for I and I45 (or for Q and Q45), as described in more detail with respect to FIG. 12.

FIG. 12 is a block diagram of an example transmit circuit 1200 including a DAC with current-steering cells, each cell configured to generate I and I45 (or Q and Q45) signals, in accordance with certain aspects of the present disclosure. For example, each of the switch drivers 1 to n may include logic to generate sw_p and sw_n signals used to control transistors 904, 906 to generate an I signal as described herein. Each of the switch drivers 1 to n may also generate switch control signals (sw_p45 and sw_n45) to control transistors 1202, 1204 to generate an I45 signal. That is, each of the current-steering cells may include additional transistors (e.g., PMOS transistors 1202, 1204 of current-steering cell 1) for generating I45 signals. The transistors 1202, 1204 (e.g., current-steering switches) may be coupled to the current source 902 and receive, at respective gates (e.g., control inputs), the sw_p45 and sw_n45 signals. The transistors 904, 906 (e.g., current-steering switches) may generate I signals provided to a BBF 1290 (e.g., corresponding to the BBF 406 of FIG. 4), and the transistors 1202, 1204 may generate I45 signals provided to a BBF 1292 (e.g., corresponding to the BBF 410). Each of the current-steering cells 1 to n may be implemented in a similar manner as current-steering cell 1 to provide I and I45 signals to respective BBFs 406, 410. A DAC for generating Q and Q45 signals may be generated in a similar manner to generate Q and Q45 signals to be provided to BBFs 408, 412.

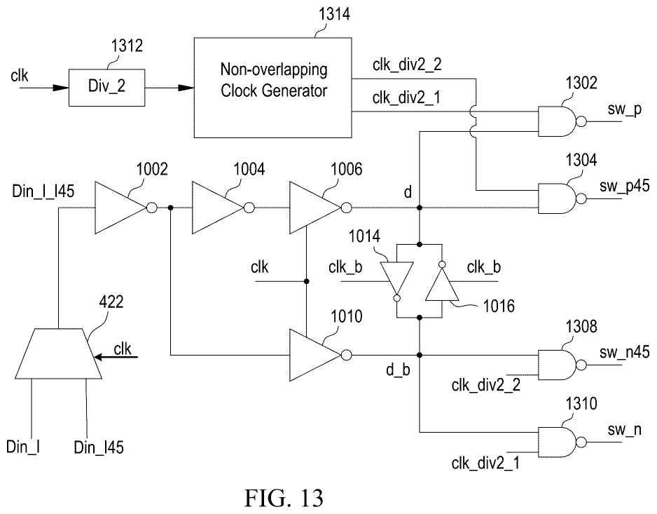

FIG. 13 is a circuit diagram of an example switch driver 1300 for generating sw_p, sw_n, sw_p45, and sw_n45 signals, in accordance with certain aspects of the present disclosure. As shown, the output of inverter 1006 may be coupled to a first input of each of NAND gates 1302, 1304, and the output of inverter 1010 may be coupled to a first input of each of NAND gates 1308, 1310. The clk signal at a clock node may be provided to a divide-by-two (DIV-2) circuit 1312 to generate a divided clock (clk_div2) signal having half the frequency of the clk signal. The clk_div2 signal may be provided to a non-overlapping clock generator 1314 to generate non-overlapping clock signals (clk_div2_1 signal and clk_div2_2 signal). The clk_div2_1 signal may be provided to a second input of each of NAND gates 1302, 1310, and the clk_div2_2 signal may be provided to a second input of each of NAND gates 1304, 1308. The NAND gates 1302, 1310 generate respective sw_p and sw_n signals, and the NAND gates 1304, 1308 generate respective sw_p45 and sw_n45 signals. Non-overlapping clock signals may be used so that the current-steering transistors (e.g., transistors 904, 906 of FIG. 12) for generating I signals are not turned on at the same time as current-steering transistors (e.g., transistors 1202, 1204 of FIG. 12) for generating the I45 signals. Thus, when the clk_div_1 signal is logic low, one of transistors 904, 906 for generating I signals may be turned on, and when the clk_div_1 signal is logic high, one of transistors 1202, 1204 for generating I45 signals may be turned on.

With the switch-driver implementation described with respect to FIG. 13, a flip-flop may be used to implement the DIV-2 circuit 1312. The NAND gates 1302, 1304, 1308, 1310 may be used instead of the inverters 1008, 1012 of FIG. 10. The current consumption of each current-steering cell (e.g., current supplied by the current source 902) may be twice the current consumption of each current-steering cell for conventional NRZ DACs.

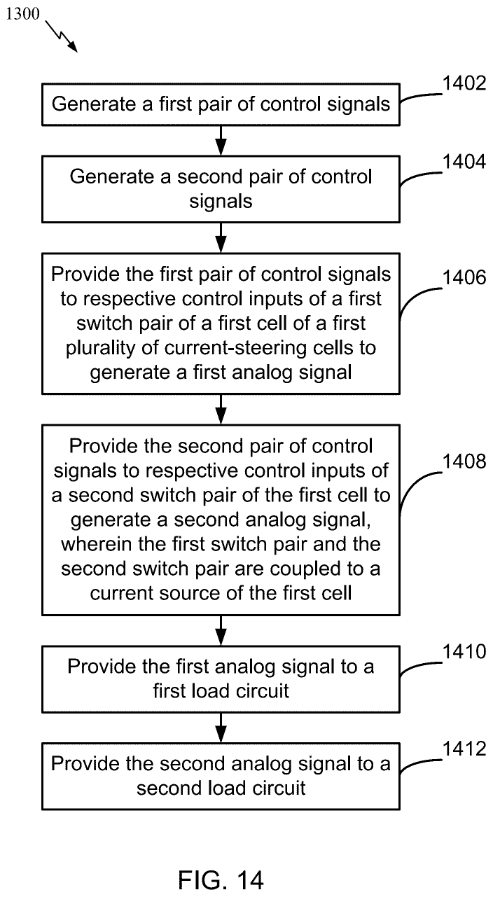

FIG. 14 illustrates example operations 1400 for digital-to-analog conversion, in accordance with certain aspects of the present disclosure. The operations 1400 may be performed by a circuit, such as the transmit circuit 1200.

At block 1402, the circuit generates a first pair of control signals (e.g., sw_p signal and sw_n signal). At block 1404, the circuit generates a second pair of control signals (e.g., sw_p45 signal and sw_n45 signal).

At block 1406, the circuit provides the first pair of control signals to respective control inputs of a first switch pair (e.g., transistors 904, 906) of a first cell of a first plurality of current-steering cells to generate a first analog signal (e.g., I signal). At block 1408, the circuit provides the second pair of control signals to respective control inputs of a second switch pair (e.g., transistors 1202, 1204) of the first cell to generate a second analog signal (e.g., I45 signal). The first switch pair and the second switch pair may be coupled to a current source (e.g., current source 902) of the first cell.

At block 1410, the circuit provides the first analog signal to a first load circuit (e.g., baseband filter 406). At block 1412, the circuit provides the second analog signal to a second load circuit (e.g., baseband filter 410).

In some aspects, generating the first pair of control signals and the second pair of control signals may include: performing a first negated AND (NAND) operation (e.g., via NAND gate 1302) based on a first clock signal (e.g., clk_div2_1 signal) and a data signal to generate a first control signal of the first pair of control signals; performing a second NAND operation (e.g., via NAND gate 1304) based on a second clock signal (e.g., clk_div2_2 signal) and the data signal to generate a first control signal of the second pair of control signals; performing a third NAND operation (e.g., via NAND gate 1308) based on a complementary data signal and the second clock signal to generate a second control signal of the second pair of control signals; and performing a fourth NAND operation (e.g., via NAND gate 1310) based on the complementary data signal and the first clock signal to generate a second control signal of the first pair of control signals. In some aspects, the first clock signal and the second clock signal may be different clock signals. In some aspects, the first clock signal and the second clock signal are non-overlapping clock signals.

In some aspects, the circuit may couple an input of the first baseband filter to a reference potential node when generating the second analog signal via the second switch pair and couple an input of the second baseband filter to the reference potential node when generating the first analog signal via the first switch pair. The first baseband filter and the second baseband filter may be return-to-zero (RZ) baseband filters.

In some aspects, the circuit may generate a third pair of control signals (e.g., corresponding to the sw_p signal, but for a DAC to generate Q and Q45 signals) and generate a fourth pair of control signals (e.g., corresponding to the sw_n signal, but for a DAC to generate the Q and Q45 signals). The circuit may provide the third pair of control signals to respective control inputs of a third switch pair (e.g., corresponding to transistors 904, 906) of a cell of a second plurality of current-steering cells to generate a third analog signal (e.g., Q signal) and provide the fourth pair of control signals to respective control inputs of a fourth switch pair (e.g., corresponding to transistors 1202, 1204) of the cell of the second plurality of current-steering cells to generate a fourth analog signal. The third switch pair and the fourth switch pair are coupled to a current source (e.g., corresponding to current source 902) of the cell of the second plurality of current-steering cells. The circuit may provide the third analog signal to a third load circuit (e.g., baseband filter 408) and provide the fourth analog signal to a fourth load circuit (e.g., baseband filter 412). In some aspects, the first analog signal comprises an I analog signal, the second analog signal comprises an I45 analog signal, the third analog signal comprises a Q analog signal, and the fourth analog signal comprises a Q45 analog signal.

### Example Aspects

In addition to the various aspects described above, specific combinations of aspects are within the scope of the present disclosure, some of which are detailed below:

Aspect 1: An apparatus for digital-to-analog conversion, comprising: a first multiplexer comprising a first input coupled to a first data input of the apparatus and a second input coupled to a second data input of the apparatus; a first digital-to-analog converter (DAC) having an input coupled to an output of the first multiplexer; and a first set of switches coupled between an output of the first DAC and a respective one of a first set of load circuits.

Aspect 2: The apparatus of Aspect 1, wherein the first set of load circuits comprises a set of baseband filters.

Aspect 3: The apparatus of Aspect 2, further comprising a set of shunt paths, each of the set of shunt paths being coupled between a reference potential node and a respective input of the set of baseband filters.

Aspect 4: The apparatus of Aspect 2 or 3, wherein input signals of the set of baseband filters comprise return-to-zero (RZ) signals.

Aspect 5: The apparatus according to any of Aspects 1-4, wherein the first DAC comprises a current-steering DAC.

Aspect 6: The apparatus according to any of Aspects 1-5, wherein: the first multiplexer is configured to provide, to the input of the first DAC, first data from the first data input of the apparatus during a first phase; and the first DAC is configured to generate a first analog signal based on the first data during the first phase, the first analog signal being provided to a first load circuit of the first set of load circuits via a first switch of the first set of switches.

Aspect 7: The apparatus of Aspect 6, wherein: the first multiplexer is configured to provide, to the input of the first DAC, second data from the second data input of the apparatus during a second phase; and the first DAC is configured to generate a second analog signal based on the second data during the second phase, the second analog signal being provided to a second load circuit of the first set of load circuits via a second switch of the first set of switches.

Aspect 8: The apparatus according to any of Aspects 1-7, further comprising: a second multiplexer comprising a first input coupled to a third data input of the apparatus and a second input coupled to a fourth data input of the apparatus; a second DAC having an input coupled to an output of the second multiplexer; and a second set of load circuits; and a second set of switches coupled between an output of the second DAC and a respective one of the second set of load circuits.

Aspect 9: The apparatus of Aspect 8, wherein: the first multiplexer is configured to provide, to the input of the first DAC, first data from the first data input of the apparatus during a first phase; the second multiplexer is configured to provide, to the input of the second DAC, third data from the third data input of the apparatus during the first phase; the first multiplexer is configured to provide, to the input of the first DAC, second data from the second data input of the apparatus during a second phase after the first phase; and the second multiplexer is configured to provide, to the input of the second DAC, fourth data from the fourth data input of the apparatus during the second phase after the first phase.

Aspect 10: The apparatus of Aspect 9, wherein: the first DAC is configured to generate a first analog signal based on the first data during the first phase, the first analog signal being provided to a first load circuit of the first set of load circuits via a first switch of the first set of switches; and the second DAC is configured to generate a second analog signal based on the third data during the first phase, the second analog signal being provided to a first load circuit of the second set of load circuits via a first switch of the second set of switches.

Aspect 11: The apparatus of Aspect 10, wherein: the first DAC is configured to generate a third analog signal based on the second data during the second phase, the third analog signal being provided to a second load circuit of the first set of load circuits via a second switch of the first set of switches; and the second DAC is configured to generate a fourth analog signal based on the fourth data during the second phase, the fourth analog signal being provided to a second load circuit of the second set of load circuits via a second switch of the second set of switches.

Aspect 12: The apparatus according to any of Aspects 8-11, wherein: the first data input comprises an in-phase (I) data input; the second data input comprises an I with 45° phase shift (I45) data input; the third data input comprises a quadrature (Q) data input; and the fourth data input comprises a Q with 45° phase shift (Q45) data input.

Aspect 13: A method for digital-to-analog conversion, comprising: providing, via a first multiplexer, first input data and second input data to an input of a first digital-to-analog converter (DAC) during a first phase and a second phase, respectively; generating, via the first DAC, a first analog signal and a second analog signal based on the first input data and the second input data during the first phase and the second phase, respectively; and providing the first analog signal and the second analog signal to a first load circuit and a second load circuit during the first phase and the second phase, respectively.

Aspect 14: The method of Aspect 13, wherein: the first load circuit comprises a first baseband filter; and the second load circuit comprises a second baseband filter.

Aspect 15: The method of Aspect 14, wherein the first analog signal and the second analog signal are provided to the first baseband filter and the second baseband filter via a first switch and second switch, respectively.

Aspect 16: The method of Aspect 15, further comprising coupling, to a reference potential node, an input of the first baseband filter and an input of the second baseband filter during the second phase and the first phase, respectively.

Aspect 17: The method of Aspect 16, wherein input signals of the first baseband filter and the second baseband filter comprise return-to-zero (RZ) signals.

Aspect 18: The method according to any of Aspects 13-17, further comprising: providing, via a second multiplexer, third input data and fourth input data to an input of a second DAC during the first phase and the second phase, respectively; generating, via the second DAC, a third analog signal and a fourth analog signal based on the third input data and the fourth input data during the first phase and the second phase, respectively; and providing the third analog signal and the fourth analog signal to a third load circuit and a fourth load circuit during the first phase and the second phase, respectively.

Aspect 19: The method of Aspect 18, wherein: the first input data comprises an in-phase (I) input data; the second input data comprises an I with 45° phase shift (I45) input data; the third input data comprises a quadrature (Q) input data; and the fourth input data comprises a Q with 45° phase shift (Q45) input data.

Aspect 20: A transmitter comprising: a set of baseband filters; a digital-to-analog converter (DAC) circuit comprising: a multiplexer comprising a first input coupled to a first data input of the DAC circuit a second input coupled to a second data input of the DAC circuit; and a DAC having an input coupled to an output of the multiplexer; a first set of switches coupled between an output of the DAC circuit and a respective one of the set of baseband filters; and a set of mixers coupled to respective outputs of the set of baseband filters.

Aspect 21: An apparatus for digital-to-analog conversion, comprising: a first plurality of switch drivers; and a first plurality of current-steering cells coupled to the first plurality of switch drivers, respectively, wherein each of the first plurality of current-steering cells comprises: a first current source; a first switch pair coupled between the first current source and a first load; and a second switch pair coupled between the first current source and a second load.

Aspect 22: The apparatus of Aspect 21, wherein each of the first plurality of switch drivers includes: a first negated AND (NAND) gate including a first input coupled to a first clock node and a second input coupled to a data node; a second NAND gate including a first input coupled to a second clock node and a second input coupled to the data node; a third NAND gate including a first input coupled to a complementary data node and a second input coupled to the second clock node; and a fourth NAND gate including a first input coupled to the complementary data node and a second input coupled to the first clock node.

Aspect 23: The apparatus of Aspect 22, wherein: an output of the first NAND gate is coupled to a control input of a first switch of the first switch pair; an output of the fourth NAND gate is coupled to a control input of a second switch of the first switch pair; an output of the second NAND gate is coupled to a control input of a first switch of the second switch pair; and an output of the third NAND gate is coupled to a control input of a second switch of the second switch pair.

Aspect 24: The apparatus of Aspect 22 or 23, wherein the first clock node and the second clock node are different nodes.

Aspect 25: The apparatus according to any of Aspects 22-24, further comprising a non-overlapping clock generator including a first output coupled to the first clock node and a second output coupled to the second clock node.

Aspect 26: The apparatus according to any of Aspects 21-25, wherein: the first load comprises a first baseband filter; and the second load comprises a second baseband filter.

Aspect 27: The apparatus of Aspect 26, further comprising: a first shunt path coupled between a reference potential node and an input of the first baseband filter; and a second shunt path coupled between the reference potential node and an input of the second baseband filter.

Aspect 28: The apparatus of Aspect 26 or 27, wherein input signals of the first baseband filter and the second baseband filter comprise return-to-zero (RZ) signals.

Aspect 29: The apparatus according to any of Aspects 21-28, further comprising: a second plurality of switch drivers; and a second plurality of current-steering cells coupled to the second plurality of switch drivers, respectively, wherein each of the second plurality of current-steering cells comprises: a second current source; a third switch pair coupled between the second current source and a third load; and a fourth switch pair coupled between the second current source and a fourth load.

Aspect 30: The apparatus of Aspect 29, wherein: the first switch pair is configured to generate an in-phase (I) analog signal; the second switch pair is configured to generate an I with 45° phase shift (I45) analog signal; the third switch pair is configured to generate a quadrature (Q) analog signal; and the fourth switch pair is configured to generate a Q with 45° phase shift (Q45) analog signal.

Aspect 31: A method for digital-to-analog conversion, comprising: generating a first pair of control signals; generating a second pair of control signals; providing the first pair of control signals to respective control inputs of a first switch pair of a first cell of a first plurality of current-steering cells to generate a first analog signal; providing the second pair of control signals to respective control inputs of a second switch pair of the first cell to generate a second analog signal, wherein the first switch pair and the second switch pair are coupled to a current source of the first cell; providing the first analog signal to a first load circuit; and providing the second analog signal to a second load circuit.

Aspect 32: The method of Aspect 31, wherein generating the first pair of control signals and the second pair of control signals comprises: performing a first negated AND (NAND) operation based on a first clock signal and a data signal to generate a first control signal of the first pair of control signals; performing a second NAND operation based on a second clock signal and the data signal to generate a first control signal of the second pair of control signals; performing a third NAND operation based on a complementary data signal and the second clock signal to generate a second control signal of the second pair of control signals; and performing a fourth NAND operation based on the complementary data signal and the first clock signal to generate a second control signal of the first pair of control signals.

Aspect 33: The method of Aspect 32, wherein the first clock signal and the second clock signal are different clock signals.

Aspect 34: The method of Aspect 32 or 33, wherein the first clock signal and the second clock signal are non-overlapping clock signals.

Aspect 35: The method according to any of Aspects 31-34, wherein: the first load circuit comprises a first baseband filter; and the second load circuit comprises a second baseband filter.

Aspect 36: The method of Aspect 35, further comprising: coupling an input of the first baseband filter to a reference potential node when generating the second analog signal via the second switch pair; and coupling an input of the second baseband filter to the reference potential node when generating the first analog signal via the first switch pair.

Aspect 37: The method of Aspect 35 or 36, wherein the first baseband filter and the second baseband filter comprise return-to-zero (RZ) baseband filters.

Aspect 38: The method according to any of Aspects 31-37, further comprising: generating a third pair of control signals; generating a fourth pair of control signals; providing the third pair of control signals to respective control inputs of a third switch pair of a cell of a second plurality of current-steering cells to generate a third analog signal; providing the fourth pair of control signals to respective control inputs of a fourth switch pair of the cell of the second plurality of current-steering cells to generate a fourth analog signal, wherein the third switch pair and the fourth switch pair are coupled to a current source of the cell of the second plurality of current-steering cells; providing the third analog signal to a third load circuit; and providing the fourth analog signal to a fourth load circuit.

Aspect 39: The method of Aspect 38, wherein: the first analog signal comprises an in-phase (I) analog signal; the second analog signal comprises an I with 45° phase shift (I45) analog signal; the third analog signal comprises a quadrature (Q) analog signal; and the fourth analog signal comprises a Q with 45° phase shift (Q45) analog signal.

Aspect 40: A transmitter comprising: a first baseband filter; a second baseband filter; a digital-to-analog converter (DAC) comprising a first plurality of switch drivers and a first plurality of current-steering cells coupled to the first plurality of switch drivers, respectively, wherein each of the first plurality of current-steering cells comprises: a first current source; a first switch pair coupled between the first current source and the first baseband filter; and a second switch pair coupled between the first current source and the second baseband filter.

### Conclusion

The above description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim. The word “exemplary” is used herein to mean “serving as an example, instance, or illustration.” Any aspect described herein as “exemplary” is not necessarily to be construed as preferred or advantageous over other aspects.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. An apparatus for digital-to-analog conversion, comprising:
a first plurality of switch drivers; and
a first plurality of current-steering cells coupled to the first plurality of switch drivers, respectively, wherein each of the first plurality of current-steering cells comprises:
a first current source;
a first switch pair coupled between the first current source and a first load; and
a second switch pair coupled between the first current source and a second load.

2. The apparatus of claim 1, wherein each of the first plurality of switch drivers includes:
a first negated AND (NAND) gate including a first input coupled to a first clock node and a second input coupled to a data node;
a second NAND gate including a first input coupled to a second clock node and a second input coupled to the data node;
a third NAND gate including a first input coupled to a complementary data node and a second input coupled to the second clock node; and
a fourth NAND gate including a first input coupled to the complementary data node and a second input coupled to the first clock node.

3. The apparatus of claim 2, wherein:
an output of the first NAND gate is coupled to a control input of a first switch of the first switch pair;
an output of the fourth NAND gate is coupled to a control input of a second switch of the first switch pair;
an output of the second NAND gate is coupled to a control input of a first switch of the second switch pair; and
an output of the third NAND gate is coupled to a control input of a second switch of the second switch pair.

4. The apparatus of claim 2, wherein the first clock node and the second clock node are different nodes.

5. The apparatus of claim 2, further comprising a non-overlapping clock generator including a first output coupled to the first clock node and a second output coupled to the second clock node.

6. The apparatus of claim 1, wherein:
the first load comprises a first baseband filter; and
the second load comprises a second baseband filter.

7. The apparatus of claim 6, further comprising:
a first shunt path coupled between a reference potential node and an input of the first baseband filter; and
a second shunt path coupled between the reference potential node and an input of the second baseband filter.

8. The apparatus of claim 6, wherein input signals of the first baseband filter and the second baseband filter comprise return-to-zero (RZ) signals.

9. The apparatus of claim 1, further comprising:
a second plurality of switch drivers; and
a second plurality of current-steering cells coupled to the second plurality of switch drivers, respectively, wherein each of the second plurality of current-steering cells comprises:
a second current source;
a third switch pair coupled between the second current source and a third load; and
a fourth switch pair coupled between the second current source and a fourth load.

10. The apparatus of claim 9, wherein:
the first switch pair is configured to generate an in-phase (I) analog signal;
the second switch pair is configured to generate an I with 45° phase shift (I45) analog signal;
the third switch pair is configured to generate a quadrature (Q) analog signal; and
the fourth switch pair is configured to generate a Q with 45° phase shift (Q45) analog signal.

11. A method for digital-to-analog conversion, comprising:
generating a first pair of control signals;
generating a second pair of control signals;
providing the first pair of control signals to respective control inputs of a first switch pair of a first cell of a first plurality of current-steering cells to generate a first analog signal;
providing the second pair of control signals to respective control inputs of a second switch pair of the first cell to generate a second analog signal, wherein the first switch pair and the second switch pair are coupled to a current source of the first cell;
providing the first analog signal to a first load circuit; and
providing the second analog signal to a second load circuit.

12. The method of claim 11, wherein generating the first pair of control signals and the second pair of control signals comprises:
performing a first negated AND (NAND) operation based on a first clock signal and a data signal to generate a first control signal of the first pair of control signals;
performing a second NAND operation based on a second clock signal and the data signal to generate a first control signal of the second pair of control signals;
performing a third NAND operation based on a complementary data signal and the second clock signal to generate a second control signal of the second pair of control signals; and
performing a fourth NAND operation based on the complementary data signal and the first clock signal to generate a second control signal of the first pair of control signals.

13. The method of claim 12, wherein the first clock signal and the second clock signal are different clock signals.

14. The method of claim 12, wherein the first clock signal and the second clock signal are non-overlapping clock signals.

15. The method of claim 11, wherein:
the first load circuit comprises a first baseband filter; and
the second load circuit comprises a second baseband filter.

16. The method of claim 15, further comprising:
coupling an input of the first baseband filter to a reference potential node when generating the second analog signal via the second switch pair; and
coupling an input of the second baseband filter to the reference potential node when generating the first analog signal via the first switch pair.

17. The method of claim 15, wherein the first baseband filter and the second baseband filter comprise return-to-zero (RZ) baseband filters.

18. The method of claim 11, further comprising:
generating a third pair of control signals;
generating a fourth pair of control signals;
providing the third pair of control signals to respective control inputs of a third switch pair of a cell of a second plurality of current-steering cells to generate a third analog signal;
providing the fourth pair of control signals to respective control inputs of a fourth switch pair of the cell of the second plurality of current-steering cells to generate a fourth analog signal, wherein the third switch pair and the fourth switch pair are coupled to a current source of the cell of the second plurality of current-steering cells;
providing the third analog signal to a third load circuit; and
providing the fourth analog signal to a fourth load circuit.

19. The method of claim 18, wherein:
the first analog signal comprises an in-phase (I) analog signal;
the second analog signal comprises an I with 45° phase shift (I45) analog signal;
the third analog signal comprises a quadrature (Q) analog signal; and
the fourth analog signal comprises a Q with 45° phase shift (Q45) analog signal.

20. A transmitter comprising:
a first baseband filter;
a second baseband filter;
a digital-to-analog converter (DAC) comprising a first plurality of switch drivers and a first plurality of current-steering cells coupled to the first plurality of switch drivers, respectively, wherein each of the first plurality of current-steering cells comprises:
a first current source;
a first switch pair coupled between the first current source and the first baseband filter; and
a second switch pair coupled between the first current source and the second baseband filter.
